(19) United States
(12) Patent Application Publication
(10) Pub. No.: US 2021/0364578 A1
(43) Pub. Date: Nov. 25, 2021

(54) CONNECTION DETECTOR AND SEMICONDUCTOR DEVICE

(71) Applicant: RENESAS ELECTRONICS CORPORATION, Tokyo (JP)

(72) Inventor: Tomoya NISHITANI, Tokyo (JP)

(21) Appl. No.: 17/318,592

(22) Filed: May 12, 2021

(30) Foreign Application Priority Data
May 22, 2020 (JP) 2020-090117

(51) Int. Cl. G01R 31/68; G06F 13/42

(52) U.S. Cl. CPC G01R 31/68; G06F 2213/0042; G06F 13/4282

(57) ABSTRACT

A connection detector includes: a power supply line for use in supply of a power supply potential; a CC terminal; a ground terminal; an electric-current output circuit arranged between the power supply line and the CC terminal and including a first switch for use in disabling an electric-current output; a pulldown resistor circuit arranged between the CC terminal and the ground terminal and including a second switch for use in disabling a pulldown resistance; a bias circuit configured to generate a first reference potential and a second reference potential that is different from the first reference potential; and a role detector including a first comparator configured to compare the first reference potential with a voltage of the CC terminal and a second comparator configured to compare the second reference potential with a voltage of the CC terminal.

### CROSS-REFERENCE TO RELATED APPLICATION

The disclosure of Japanese Patent Application No. 2020-090117 filed on May 22, 2020, including the specification, drawings and abstract is incorporated herein by reference in its entirety.

### BACKGROUND

The present application relates to a connection detector, and, more particularly relates to a technique effectively applied to a semiconductor device on which a USB (Universal Serial Bus) IF (Interface) is mounted, and a microcontroller and a system LSI including the USB IF that is connectable to a USB Type-C connector.

Along with popularization of a USB (Universal Serial Bus), there is the increasing need to unify shapes of a plurality of existing connectors such as USB Type-A and Type-B, Micro USB and others, and therefore, USB Type-C standards have been commercialized as new standards related to a connector and a cable.

There are disclosed techniques listed below.

[Non-Patent Document 1] “Universal Serial Bus Type-C Cable and Connector Specification, Release 2.0, August 2019”

As a USB Type-C standard documentation, “Universal Serial Bus Type-C Cable and Connector Specification”, Release 2.0, August 2019, is exemplified.

When the Type-C connector and its function are mounted on a USB device, a connector shape can be downsized, and connection between the connectors becomes easy since it is unnecessary to recognize difference between front and back sides of the connector. In comparison with the existing USB standards prior to the USB Type-C, the USB Type-C standards have various advantages such as achievement of power supply to and reception from a VBUS power supply and achievement of the image data transmission without usage of a dedicated port such as High-Definition Multimedia Interface, Display Port and others.

In the USB Type-C standard documentation, a power supply side is called “Source”, and a power reception side is called “Sink”. And, there is a general idea of “Dual Role Power (DRP)” in which the functional roles of the Source and the Sink are allowed to be periodically switched at the time of disconnection. This switching period is called “DRP Timing”. The following explanations are made in an assumption that the USB IF is compliant with the DRP.

### SUMMARY

The existing USB standards prior to the commercialization of the USB Type-C connector define two roles that are the “Host” and the “Peripheral” as the roles in the data transfer, and the Peripheral is configured to passively operate in accordance with a command from the Host. And, until the commercialization of the USB Type-C connector, devices having the same roles have not been connected to each other since the connectors for the Host and the Peripheral have different shapes from each other in order to recognize difference between their roles.

However, the USB Type-C standards have a possibility of the connection between the devices having the same roles since there is no difference in the connector shape. That is, there is a possibility of connection between the Sources having different power supply voltages from each other. The case of the connection between the Sources having different power supply voltages from each other has a concern of breakage of a semiconductor element configuring a connection detector (CCPHY) that is provided inside the USB IF.

An objective of the present application is to provide a technique capable of preventing the breakage of the semiconductor element even in the case of the connection between the Sources having the different power supply voltages from each other.

Other objects and novel characteristics will be apparent from the description of the present specification and the accompanying drawings.

The summary of the typical aspects disclosed in the present application will be briefly described as follows.

A connection detector according to an embodiment includes: a power supply line for use in supply of a power supply potential; a CC terminal; a ground terminal; an electric-current output circuit arranged between the power supply line and the CC terminal and including a first switch for use in disabling an electric-current output; a pulldown resistor arranged between the CC terminal and the ground terminal and including a second switch for use in disabling a pulldown resistance; a bias circuit configured to generate a first reference potential and a second reference potential that is different from the first reference potential; and a role detector including a first comparator configured to compare the first reference potential and a voltage of the CC terminal and a second comparator configured to compare the second reference potential and the voltage of the CC terminal, and the first switch and the second switch are simultaneously turned ON in a Dual Role Power (DRP) Timing period defined in the Universal Serial Bus (USB) Type-C standards, and the Role detector is used to detect a role of a counterpart device by comparison between the first and second reference potentials and the voltage level of the CC terminal that is defined by a connection state with the counterpart device.

### BRIEF DESCRIPTIONS OF THE DRAWINGS

FIG. 1 is a circuit diagram showing a configuration example of a CCPHY studied by the present inventors on the basis of a configuration of a CCPHY described in a USB Type-C standard documentation.

FIG. 2 is a diagram showing a connection example in connection of a counterpart device having a Sink function to a CC1 terminal of a CCPHY 10r operating as a Source.

FIG. 3 is a diagram showing a connection example in connection of a counterpart device having a Source function to a CC1 terminal of a CCPHY 10r operating as a Source.

FIG. 4 is a circuit diagram showing a configuration example of a connection detector (CCPHY) for use in a Configuration Channel according to a first working example.

FIG. 5 is a diagram showing a combination of a connection state of devices related to a CC1 terminal and a CC2 terminal.

FIG. 6 is a diagram showing a DRP Timing period defined in the Type-C standards.

FIG. 7 is a diagram schematically showing a connection state of a counterpart device 20 operating as the Source in a state in which a switch SW1 and a switch SW2 in the CCPHY 10 are simultaneously turned ON.

FIG. 8 is a diagram schematically showing a connection state of the counterpart device 20 operating as the Sink in the state in which the switch SW1 and the switch SW2 in the CCPHY 10 are simultaneously turned ON.

FIG. 9 is a diagram schematically showing a connection state of the counterpart device 20 operating as a Powered-C in the state in which the switch SW1 and the switch SW2 in the CCPHY 10 are simultaneously turned ON.

FIG. 10 is a diagram schematically showing an Open state of a CC terminal in the state in which the switch SW1 and the switch SW2 in the CCPHY 10 are simultaneously turned ON.

FIG. 11 is a diagram showing a range of variation of output voltage levels (V1, V2, V3 and V4) of the CC terminal at the time of the operation of the Role detection.

FIG. 12 is a diagram showing classification of the combination of the connection states shown in FIG. 5 into four groups of A, B, C and D.

FIG. 13 is a diagram showing a configuration example of a semiconductor device including a USB IF.

FIG. 14 is a flowchart showing an operational flow of the CCPHY 10 of FIG. 4.

FIG. 15 is a diagram showing a connection example in connection of the counterpart device having the Source function to the CC1 terminal of the CCPHY 10 operating as the Source.

FIG. 16 is a circuit diagram showing a configuration example of a CCPHY 10a according to a second working example.

### DETAILED DESCRIPTION

Embodiments and working examples will be described below with reference to the drawings. In the following description, the same elements are denoted with the same reference symbols, and the repetitive description thereof will be omitted in some cases. Also, in order to make the clear description for the drawings, the drawings are illustrated to be more schematic than those in an actual aspect in some cases. However, the illustration is only one example, and does not limit the interpretation of the present invention.

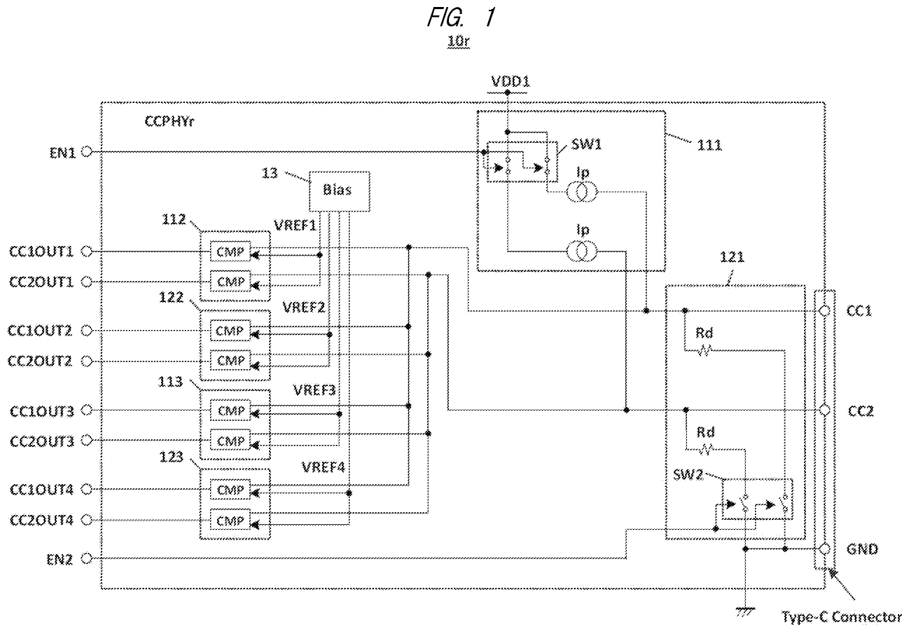

First, with reference to FIGS. 1, 2 and 3, issues will be explained. Note that FIGS. 1, 2 and 3 show not the publicly-known technique but the technique studied by the present inventors.

A connection detector for “Configuration Channel” (hereinafter, referred to as “CCPHY”) is exemplified as a necessary function for the mounting of the USB (Universal Serial Bus) Type-C connector. The CCPHY has functions of detecting the connection/disconnection of the USB port, determining the front/back side at the time of the connection of the connector, and making an alert for and detecting a power supply ability of the VBUS power supply, by using a first terminal for the Configuration Channel (hereinafter, referred to as CC1 terminal) and a second terminal for the Configuration Channel (hereinafter, referred to as CC2 terminal).

FIG. 1 is a circuit diagram showing a configuration example of a CCPHY studied by the present inventors on the basis of a configuration of the CCPHY defined in the USB Type-C standard documentation.

AS shown in FIG. 1, a CCPHY 10r is configured of a Source circuit 11, a Sink circuit 12 and a bias generator 13.

The Source circuit 11 includes an electric-current output circuit 111, a Sink connection detector 112, and a powered-cable connection detector 113. The powered cable (hereinafter, referred to as “Powered-C”) is a cable included in a repeater or a device operating when receiving power supply from the Source, and is made different from a device having the Sink function.

The Sink circuit 12 includes a pulldown resistor 121, a Source connection detector 122 and an electric-current supply ability detector 123. The electric-current supply ability is one item of the so-called USB Type-C Current standards, and indicates the maximum value of the suppliable electric current from the VBUS power supply of the Source. When the Source is compliant with the USB Type-C standards, electric currents of 1.5 A and 3.0 A are suppliable in addition to the electric current values (500 mA in the case of the USB 2.0, 900 mA in the case of the USB 3.x, each of which is called a Default electric current in the standards) defined in the existing USB standards prior to the USB Type-C standards.

The electric-current output circuit 111 has an electric-current source “Ip” for each CC terminal (in this case, the CC1 terminal and the CC2 terminal are collectively described as the CC terminal), and includes the first switch SW1 for use in disabling the electric-current output when the device operates as the Sink. The first switch SW1 is connected between the electric-current source Ip and a power supply line for use in supply of a power supply potential VDD1. The electric-current source Ip is arranged between the first switch SW1 and the CC terminal. ON state/Off state of the first switch SW1 are controlled by using a first input enable terminal EN1.

The pulldown resistor 121 has a pulldown resistor “Rd” for each CC terminal, and includes the second switch SW2 for use in disabling the pulldown resistance Rd when the device operates as the Source. The second switch SW2 is connected between the pulldown resistance Rd and a ground terminal GND. The pulldown resistance Rd is arranged between the CC terminal and the second switch SW2. ON state/Off state of the second switch SW2 are controlled by using a second input enable terminal EN2.

Each of the Sink connection detector 112, the Powered-C connection detector 113, the Source connection detector 122 and the electric-current supply ability detector circuit 123 has a comparator circuit CMP for each CC terminal, and the bias generator 13 supplies reference voltages of four types (VREF1, VREF2, VREF3 and VREF4), voltage values of which are different from one another, to these detectors (112, 113, 122 and 123).

The comparator circuits CMP of the respective detector circuits (112, 113, 122 and 123) output a determination result of the input voltage level of the CC1 terminal to output terminals CC1OUT1, CC1OUT2, CC1OUT3 and CC1OUT4, and output a determination result of the input voltage level of the CC2 terminal to output terminals CC2OUT1, CC2OUT2, CC2OUT3 and CC2OUT4.

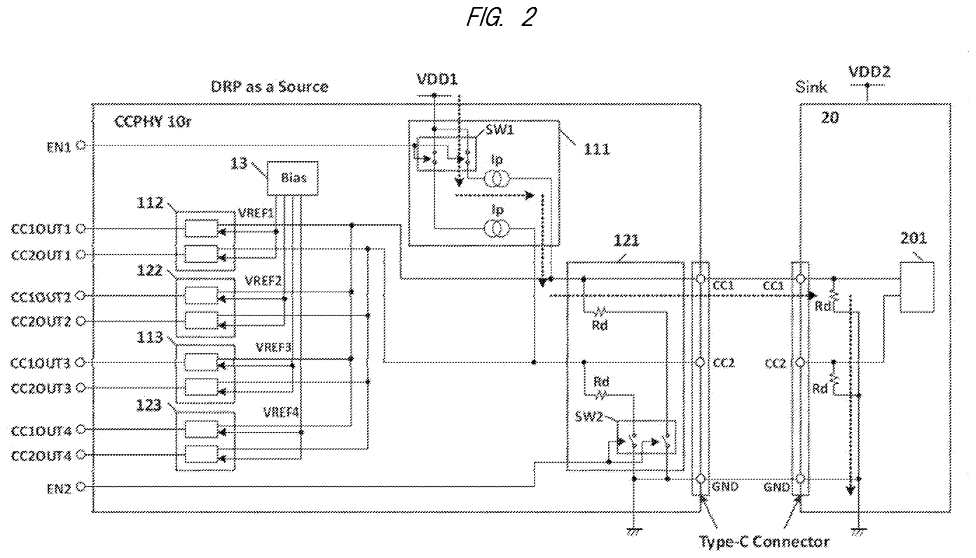

FIG. 2 is a diagram showing a connection example in connection of a counterpart device having the Sink function to the CC1 terminal of the CCPHY 10r operating as the Source. The counterpart device 20 is assumed to have a connection detector 201 and the pulldown resistance Rd connected to each CC terminal.

In the CCPHY 10r and the counterpart device 20, the connection state is determined by using the detectors (112, 113, 122 and 123) to monitor the voltage levels of the CC1 terminal and the CC2 terminal determined by the electric-current source Ip for the Source and the pulldown resistance Rd of the counterpart device 20. In FIG. 2, a dotted arrow shows an electric-current path flowing from the Source to the Sink through the CC1 terminal in this case. In FIG. 2, the electric current flows from the power supply VDD1 to the GND terminal of the counterpart device 20, and therefore, the element does not deteriorate in the characteristics or is not broken.

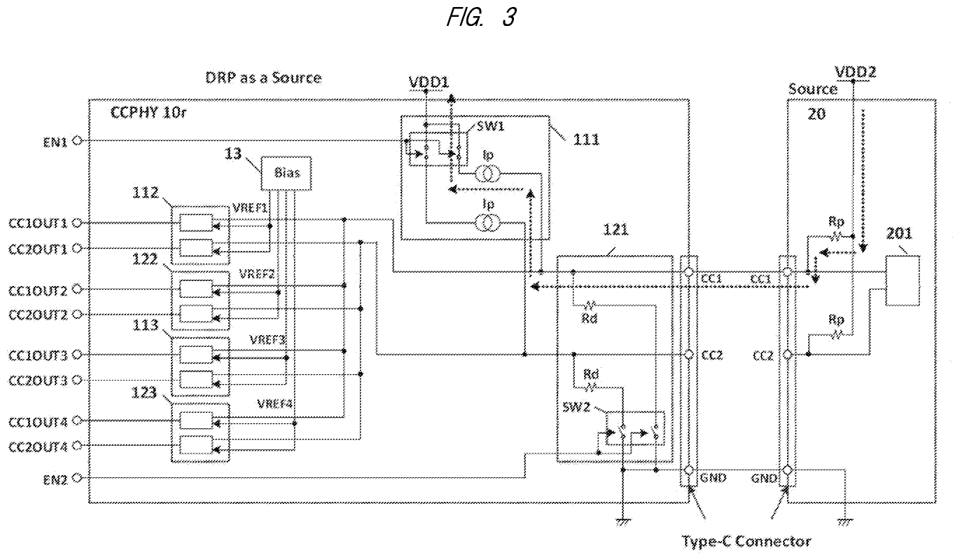

FIG. 3 is a diagram showing a connection example in connection of the counterpart device having the Source function to the CC1 terminal of the CCPHY 10r operating as the Source. The counterpart device 20 is assumed to have a connection detector 201 and a pullup resistance Rp connected to each CC terminal.

In the USB Type-C standards, the device operating as the Source is configured to have the pullup resistance Rp or the electric-current source Ip, both of which are connected to a 5.0 V- or 3.3 V-power supply. Therefore, the power supply voltage VDD1 connected to the electric-current source Ip included in the CCPHY 10r operating as the Source and a power supply voltage VDD2 connected to the pullup resistance Rp included in the counterpart device 20 are different from each other in some cases.

When it is assumed that the power supply voltage value of the power supply voltage VDD1 is 3.3 V while the power supply voltage value of the power supply voltage VDD2 is 5.0 V, the electric current path is generated from the power supply voltage VDD2 toward the power supply voltage VDD1 at the time of the connection of the counterpart device 20 as shown with the dotted arrow in FIG. 3. In this case, because of overcurrent flow, there is a concern about the deterioration of the electric characteristics of the semiconductor element configuring the electric-current output circuit 111 connected through the CC1 terminal or about increase in the voltage of the CC1 terminal to exceed the absolute maximum rating of the semiconductor element, which results in the breakage of the semiconductor element itself.

The present disclose relates to a circuit configuration and an operational flow for preventing the characteristic deterioration and the breakage of the internal element due to the electric-current path and the overvoltage generated in the connection between the CCPHYs having the different conditions of the power supply voltages in use from each other.

Hereinafter, the embodiments will be explained with reference to the drawings.

### First Working Example

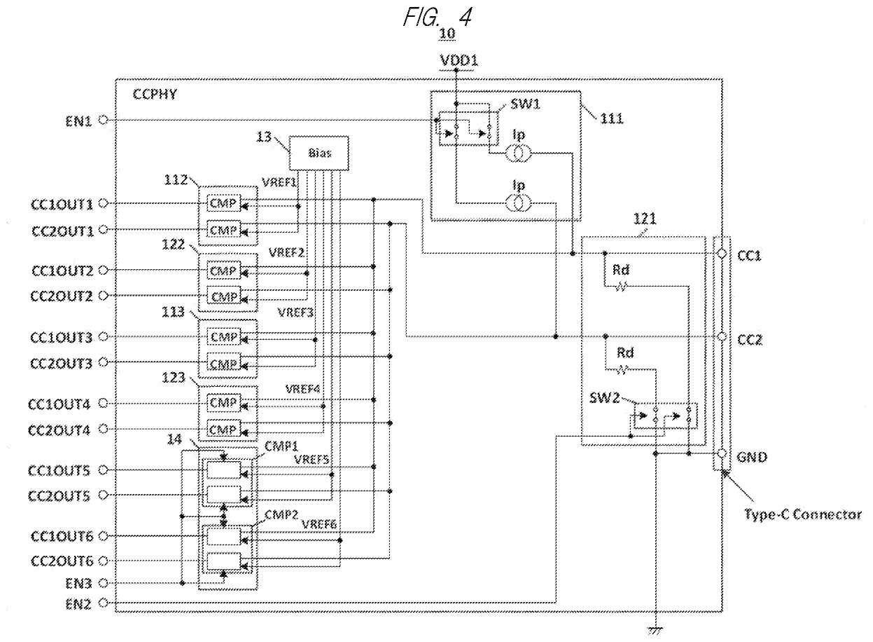

FIG. 4 is a circuit diagram showing a configuration example of the connection detector (CCPHY) for the Configuration Channel according to a first working example.

As shown in FIG. 4, the connection detector (CCPHY) for the Configuration Channel 10 is configured of the Source circuit 11, the Sink circuit 12, the bias generator 13 and the Role detector 14. The Source circuit 11 and the Sink circuit 12 are the same in the configurations as those of FIG. 1, and therefore, the explanation for them is omitted.

The Role detector 14 has comparators of two types (a first comparator CMP1 and a second comparator CMP2) having different reference voltages for each CC terminal (CC1 terminal and CC2 terminal), and ON state/Off state of each of the comparators CMP1 and CMP2 are controlled by using an input enable terminal EN3.

The bias generator 13 supplies the reference voltages of four types (VREF1, VREF2, VREF3 and VREF4), voltage values of which are different from one another, to each of the Sink connection detector 112, the Powered-C connection detector 113, the Source connection detector 122 and the electric-current supply ability detector 123 as similar to FIG. 1, and besides, supplies reference voltages of two types (VREF5 and VREF6), voltage values of which are different from each other, to the comparators CMP1 and CMP2 included in the Role detector 14.

The comparator circuit CMP1 of the Role detector 14 outputs the determination result of the input voltage level of the CC1 terminal, to an output terminal CC1OUT5, and outputs the determination result of the input voltage level of the CC2 terminal, to an output terminal CC2OUT5. The comparator circuit CMP2 outputs a determination result of the input voltage level of the CC1 terminal, to an output terminal CC1OUT6, and outputs a determination result of the input voltage level of the CC2 terminal, to an output terminal CC2OUT6.

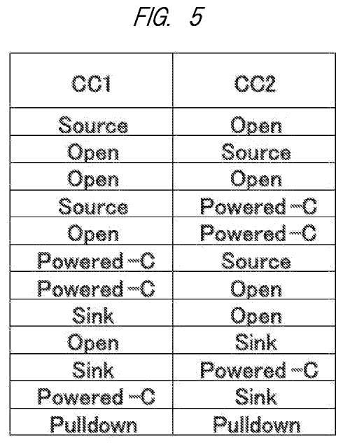

Next, combination of the counterpart device connected to the CC terminal will be explained. FIG. 5 is a diagram showing the combination of the device connection state related to the CC1 terminal and the CC2 terminal.

As the connection state of the CC terminal, any one of the Source device, the Sink device, the connection with the Powered-C, a non-connection (hereinafter, referred to as “Open”) state is expected. The simultaneous connections of the Source and the Sink to the CC1 terminal and the CC2 terminal, the Sink and the Source thereto, the Source and the Source thereto and the Sink and the Sink thereto are impossible to occur. Therefore, in consideration except for these cases, the combination of the device connection state related to the CC1 terminal and the CC2 terminal is as shown in FIG. 5. Note that the combination includes a unique state (in which both the CC1 terminal and the CC2 terminal are Pulled down).

The CCPHY 10 determines the device connection state shown in FIG. 5 by simultaneously turning ON the switch SW1 included in the electric-current output circuit 111 and the switch SW2 included in the pulldown resistor 121, and using the comparator CMP1 and the comparator CMP2 of the Role detector 14 to compare the reference voltages (VREF5, VREF6) supplied from the bias generator 13 with the voltage levels of the CC1 terminal and the CC2 terminal depending on the connected counterpart device.

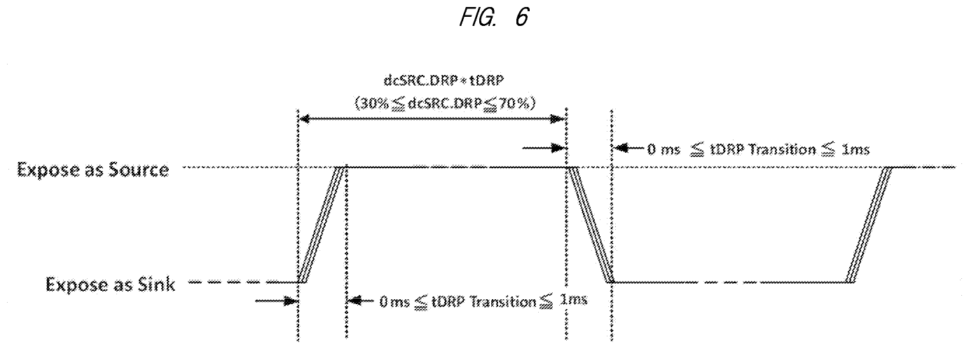

Next, the operation of the CCPHY 10 will be explained. FIG. 6 is a diagram showing the DRP Timing period defined in the USB Type-C standards.

A term “tDRP” represents a cycle of the switching between the Source and the Sink.

A term “dcSRC.DRP” represents a ratio of the operation as the Source in the tDRP, and the ratio can be determined in a range from 30% to 70% by a user.

A term “tDRP Transition” represents transition time taken for transition from the Source to the Sink or from the Sink to the Source. The transition time is allowed up to 1 ms at the maximum, and a signal observed at the CC terminal during this time can be ignorable in the standards.

In the present application, this “tDRP Transition” period (referred to as “DRP Timing period”) is used. In this manner, the combination of the device connection state can be determined without affecting the practical USB Type-C communication.

The CCPHY 10 enables the Role detector 14 by simultaneously turning ON the switch SW1 included in the electric-current output circuit 111 and the switch SW2 included in the pulldown resistor 121 at the timing of the switching from the Source to the Sink or from the Sink to the Source in the DRP timing period to activate the third input enable signal EN3.

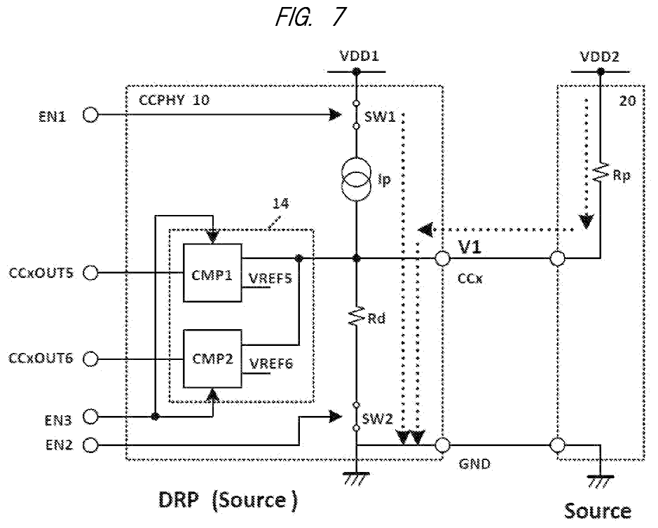

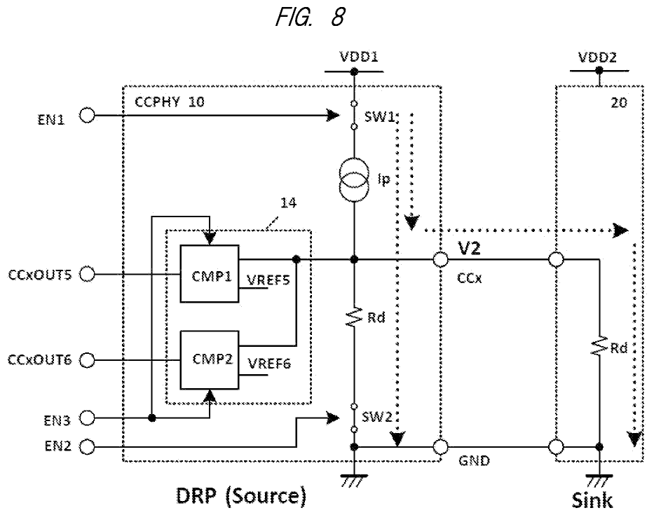

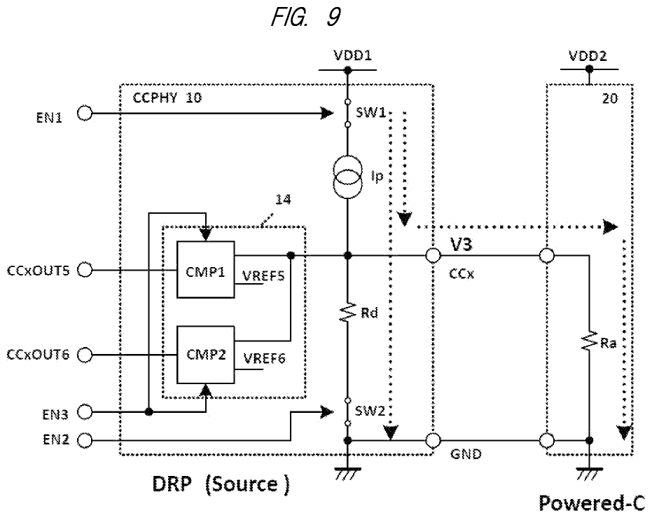

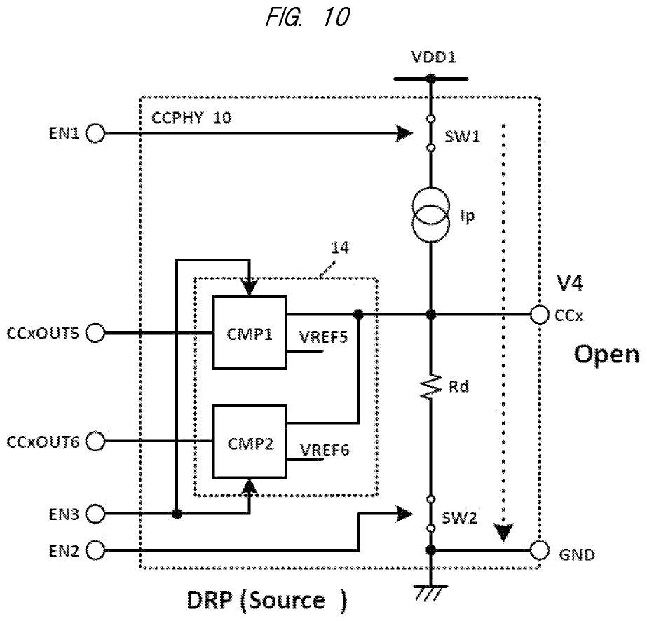

FIG. 7 is a diagram schematically showing a connection state of the counterpart device 20 operating as the Source in a state in which the switch SW1 and the switch SW2 in the CCPHY 10 are simultaneously turned ON. FIG. 8 is a diagram schematically showing a connection state of a counterpart device 20 operating as the Sink in the state in which the switch SW1 and the switch SW2 in the CCPHY 10 are simultaneously turned ON. FIG. 9 is a diagram schematically showing a connection state of the counterpart device 20 operating as the Powered-C in the state in which the switch SW1 and the switch SW2 in the CCPHY 10 are simultaneously turned ON. FIG. 10 is a diagram schematically showing the Open state of the CC terminal in the state in which the switch SW1 and the switch SW2 in the CCPHY 10 are simultaneously turned ON. In FIGS. 7, 8, 9 and 10, a dotted arrow indicates the electric current path in each connection state.

Here, a connecting operation of the Powered-C shown in FIG. 9 will be supplementarily explained. At the time of the connection of the Powered-C, either one of the CC terminals is pulled down by the pulldown resistance Ra. At this time, a relation of “Ra<Rd” is made between the pulldown resistance Rd and the pulldown resistance Ra. The CCPHY 10 monitors the voltage level of the CC terminal determined by the electric-current source Ip for the Source and the pulldown resistance Ra by using the Powered-C detector 113, and determines the connection state.

Output voltage levels V1, V2, V3 and V4 shown in FIGS. 7, 8, 9 and 10 indicate the voltage levels of the CC terminal in each connection state. In calculation based on the values of Ip, Rp, Rd and Ra defined in the standards, a relation “V3<V2<V4<V1” is made among the Typical values of these output voltage levels V1, V2, V3 and V4. The Role detector 14 only needs to determine which one of the CC terminals is connected to the Source. Therefore, as long as this relation is secured, the reference voltage values may be determined so that a threshold is put between the output voltage level V1 and the voltage V4.

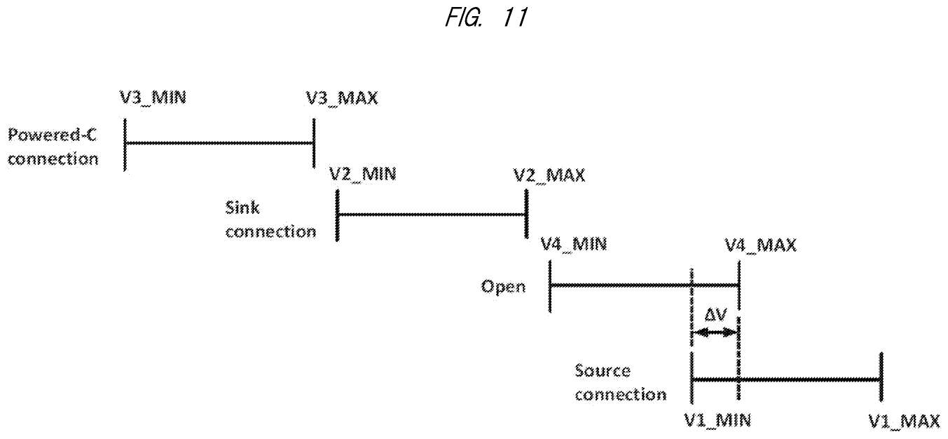

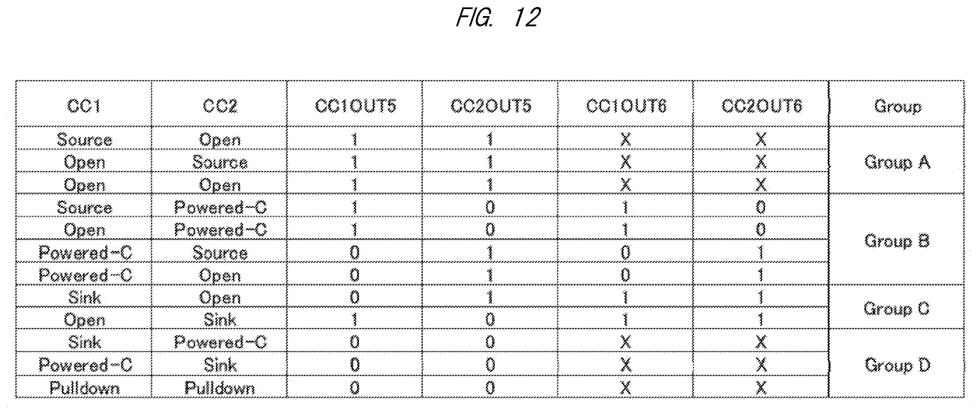

FIG. 11 is a diagram showing a range of variation of the output voltage levels (V1, V2, V3 and V4) of the CC terminal at the time of the operation of the Role detection. FIG. 12 is a diagram showing classification of the combination of the connection states shown in FIG. 5 into four groups of A, B, C and D.

As shown in FIG. 11, in consideration of the variation of the voltage values of the output voltage level V1 and the output voltage level V4, an overlap (ΔV) is caused in the range of the variation of the voltages, and the relation between the maximum value of the output voltage level V4 and the minimum value of the output voltage level V1 is flipped in some cases. Therefore, the reference voltages of the comparator CMP1 and the comparator CMP2 of the role detector 14 are not allowed to be set between the output voltage level V1 and the output voltage level V4. This is because, if the reference voltages are set between the output voltage level V1 and the output voltage level V4, the Open state is possibly erroneously determined even when the Source is connected to the CC terminal, which results in the Source-to-Source connection.

In order to solve this problem, the CCPHY 10 determines the combination in the connection of the counterpart device 20 to the CC terminal by using the comparators of two types that are the comparator CMP1 and the comparator CMP2 of the Role detector 14. When the comparator CMP1 detects the voltage level of the CC terminal to be equal to or higher than the reference voltage VREF5, the outputs of the output terminals CC1OUT5 and CC2OUT5 are set to change from a low level “0” such as a first level to a high level “1” such as a second level different from the first level. When the comparator CMP2 detects the voltage level of the CC terminal to be equal to or higher than the reference voltage VREF6, the outputs of the output terminals CC1OUT6 and CC2OUT6 are set to change from the low level “0” to the high level “1”.

The reference voltage VREF5 of the comparator CMP1 is set between the output voltage level V2 and the output voltage level V4, and the reference voltage VREF6 of the comparator CMP2 is set between the output voltage level V2 and the output voltage level V3. In this manner, by the combination of the output states of the output terminals CC1OUT5, CC2OUT5, CC1OUT6 and CC2OUT6, the combination of the connection states shown in FIG. 5 can be classified into the four groups A, B, C and D as shown in FIG. 12. When it is determined which group (A, B, C or D) the combination belongs to, the role of the counterpart device 20 can be detected. The reason why the Role detector 14 is not configured of only the comparator CMP1 is that the combination of the Source connection in the group B and the Sink connection in the group C cannot be made difference. If the Role detector 14 is configured of only the comparator CMP1, the Sink connection is possibly erroneously determined although the Source is connected to the CC terminal, which results in the connection between the Sources. Therefore, a devisal using the comparator CMP2 to make the difference is made to the CCPHY 10 so as not to make the erroneous determination.

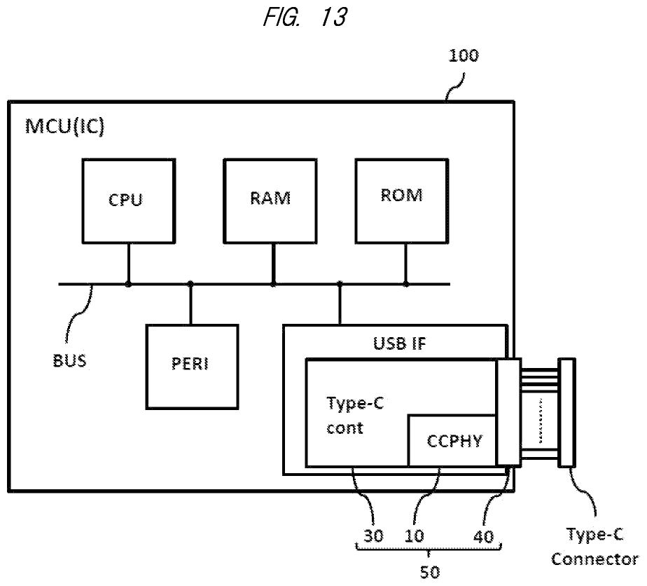

FIG. 13 is a diagram showing a configuration example of a semiconductor device including the USB IF. A semiconductor device (IC) 100 configures a microcontroller MCU including a central processor CPU, a volatile memory RAM, a non-volatile memory ROM, a peripheral circuit PERI, an USB IF 50, and a bus BUS that connect these circuits (CPU, RAM, ROM, PERI and USB IF). The USB IF 50 includes the CCPHY 10, a Type-C controller “Type-C cont” 30 and an USB port 40. The USB port 40 is electrically connected to the USB Type-C Connector.

Although not illustrated, the USB Type-C Connector includes an A row and a B row as defined in the USB Type-C standards. The Type-C Connector includes totally 24 pins that are 12 pins (pin numbers A1 to A12) in the A row and 12 pins (pin numbers B1 to B12) in the B row. In these pins, the A row and the B row are rotationally symmetric to each other.

The A row includes GND pins (pin numbers A1 and A12), a CC1 pin (pin number A5) for a configuration signal, D+ pin and D− pin (pin numbers A6 and A7) for a transmission/reception signal of a first USB communication mode, TX1+ pin and TX1− pin (pin numbers A2 and A3) for a transmission signal of a second USB communication mode, RX2+ pin and RX2− pin (pin numbers A10 and A11) for a reception signal of the second USB communication mode, VBUS pins (pin numbers A4 and A9) for a power supply line, and an SBU1 pin (pin number A8) for sideband.

The B row includes GND pins (pin numbers B1 and B12), a CC2 pin (pin number B5) for a configuration signal, D+ pin and D− pin (pin numbers B6 and B7) for a transmission/reception signal of the first USB communication mode, TX2+ pin and TX2− pin (pin numbers B2 and B3) for a transmission signal of the second USB communication mode, RX1+ pin and RX1− pin (pin numbers B10 and B11) for a reception signal of the second USB communication mode, VBUS pins (pin numbers B4 and B9) for a power supply line, and an SBU2 pin (pin number B8) for sideband.

For example, the first USB communication mode is an USB 2.0 mode, and the second USB communication mode is an USB 3.2 mode. The CC1 pin (pin number A5), the CC2 pin (pin number B5) for a configuration signal, and the GND pins (pin numbers A1 and A12) correspond to the CC1 terminal, the CC2 terminal and the ground terminal GND in FIG. 4.

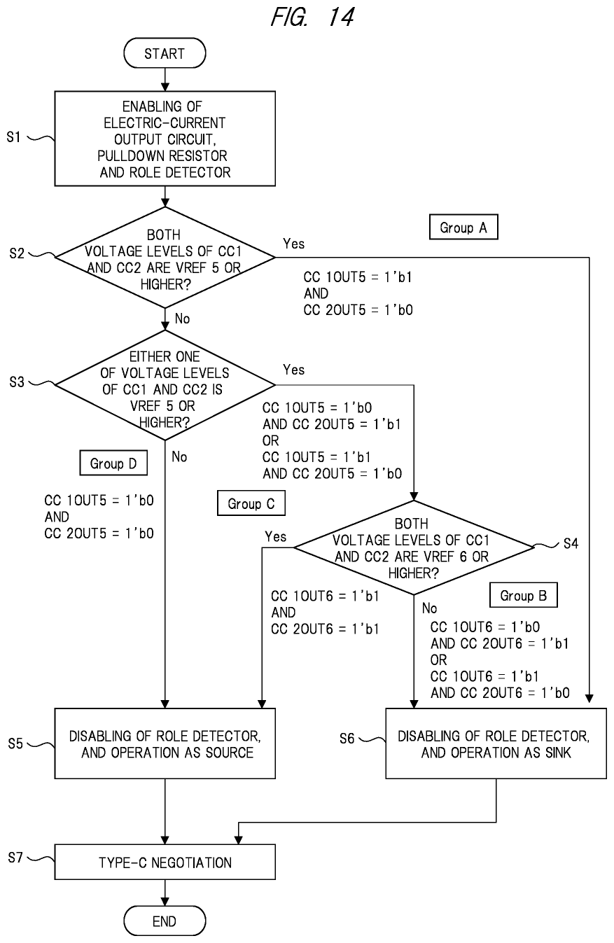

FIG. 14 is a flowchart showing an operational flow of the CCPHY 10 of FIG. 4. The groups A, B, C and D in the flowchart correspond to the groups A, B, C and D in FIG. 10. Note that the conditions of the output terminals CC1OUT1, CC1OUT2, CC1OUT3, CC1OUT4, CC2OUT1, CC2OUT2, CC2OUT3, CC2OUT4, CC1OUT5, CC2OUT5, CC1OUT6 and CC2OUT6 in FIG. 14 would be obviously understood from FIG. 14 by those who skilled in the art, and therefore, the explanation for the conditions is omitted.

Along the operational flow of FIG. 14, the Type-C controller 30 disables the Role detector 14 in response to the detection result that is the connection between the Source and the Open, the Open state at both terminals (CC1 terminal and CC2 terminal) or the connection between the Source and the Powered-C as the combination of the connection of the counterpart device to the CC terminal, and then, the switch SW1 is turned OFF to make the transition to the Sink mode. In this manner, the connection between the Sources can be avoided.

(Step S1)

The Type-C controller 30 enables the electric-current output circuit 111, the pulldown resistor 121 and the Role detector 14 by activating the first input enable terminal EN1, the second input enable terminal EN2 and the third input enable terminal EN3.

(Step S2)

It is determined whether both the voltage levels of the CC1 terminal and the CC2 terminal are equal to or higher than the reference voltage VREF5. If the determination is “Yes”, the flow proceeds to a step S6. If the determination is “No”, the flow proceeds to a step S3.

(Step S3)

It is determined whether either the voltage level of the CC1 terminal or the CC2 terminal is equal to or higher than the reference voltage VREF5. If the determination is “Yes”, the flow proceeds to a step S4. If the determination is “No”, the flow proceeds to a step S5.

(Step S4)

It is determined whether both the voltage levels of the CC1 terminal and the CC2 terminal are equal to or higher than the reference voltage VREF6. If the determination is “Yes”, the flow proceeds to the step S5. If the determination is “No”, the flow proceeds to the step S6.

(Step S5)

The type-C controller 30 disables the Role detector 14, and operates the device as the Source. Then, the flow proceeds to a step S7.

(Step S6)

The type-C controller 30 disables the Role detector 14, and operates the device as the Sink. Then, the flow proceeds to the step S7.

(Step S7)

The type-C controller 30 performs Type-C negotiation to the connected Sink device or Source device.

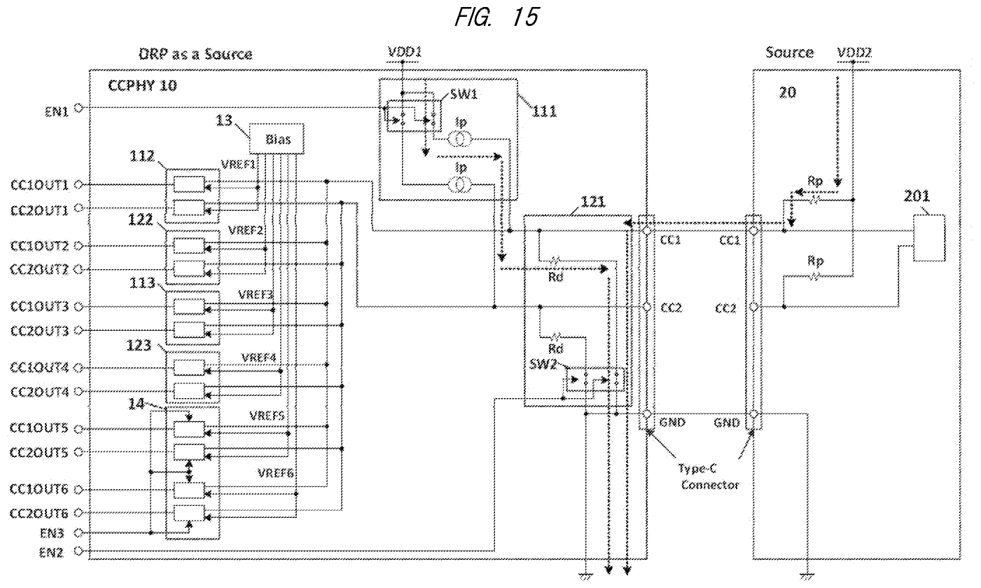

FIG. 15 is a diagram showing a connection example in connection of the counterpart device having the Source function to the CC1 terminal of the CCPHY 10 operating as the Source. The power supply voltage VDD1 of the CCPHY 10 is assumed to be 3.3 V, and the power supply voltage VDD2 of the counterpart device is assumed to be 5.0 V. When the switch SW1 and the switch SW2 in the CCPHY 10 are simultaneously turned ON, the electric-current path is generated from the power supply voltages VDD1 and VDD2 to the GND, and therefore, the generation of the electric-current path from the power supply voltage VDD2 to the power supply voltage VDD1 as shown in FIG. 3 can be suppressed.

One configuration example of the first working example can be summarized as follows although not particularly limited.

The semiconductor device includes the type-C controller 30 and the CCPHY 10.

The CCPHY 10 includes: the electric-current output circuit 111 including the first switch SW1 for use in disabling the electric-current output Ip; the Source circuit 11 including the Sink-connection detector 112 having the comparator CMP and the powered-C detector 113; the pulldown resistor 121 including the second switch SW2 for use in disabling the pulldown resistance Rd; the Sink circuit 12 including the Source-connection detector 122 having the comparator CMP and the electric-current supply ability detector 123; the Role detector 14 having the comparators of two types (CMP1 and CMP2) having difference reference voltages; and the bias generator 13 supplying the reference voltages (VREF1 to VREF6) to each of the detectors (112, 113, 122 and 123) and the Role detector 14.

The Type-C controller 30 simultaneously turns ON the first switch SW1 and the second switch SW2 in the DRP Timing period defined in the Type-C standards, and detects the role of the counterpart device 20 by using the Role detector 14 to compare the reference voltages (VREF5 and VREF6) with the voltage levels of the CC terminals (CC1 terminal and CC2 terminal) depending on the connection state of the counterpart device 20.

According to the first working example, the following effects can be obtained.

1) As a first effect, the deterioration and the breakage of the element can be prevented. The reason is as follows. The first switch SW1 and the second switch SW2 are simultaneously turned ON in the DRP timing period to generate the electric-current path toward the ground terminal GND. In this manner, the electric-current flow from the power supply voltage VDD2 of the counterpart device 20 toward the power supply voltage VDD1 of the CCPHY 10 is suppressed.

2) As a second effect, the connection between the Sources can be avoided. The reason is as follows. The voltage levels (V1 to V4) in the Open state and the states of the connections of the Source, the Sink and the Powered-C to the CCPHY 10 and the counterpart device 20 can be previously calculated from the values of the pullup resistance Rp, the electric-current source Ip and the pulldown resistances Rd and Ra defined in the standards, and then, the reference voltage values (VREF5 and VREF6) of the Role detector 14 based on the calculation results can be set. In this manner, the connection of the Source to the counterpart device 20 can be detected.

### Second Working Example

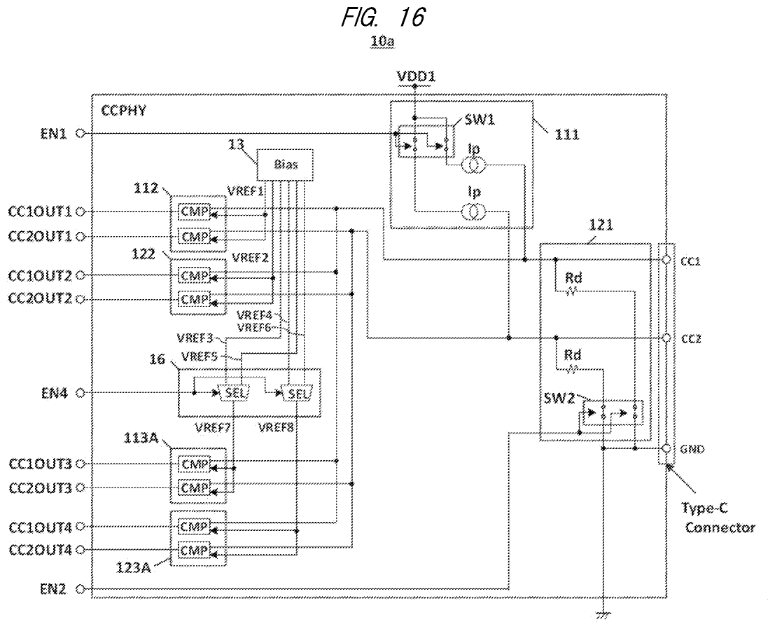

FIG. 16 is a circuit diagram showing a configuration example of a CCPHY 10a according to a second working example.

The CCPHY 10 of the first working example has an issue of a larger circuit scale than that of the CCPHYr 10r because of the addition of the Role detector 14. A circuit made in consideration of solution for this issue is the CCPHY 10a of the second working example shown in FIG. 16.

The CCPHY 10a is configured of the Source circuit 11, the Sink circuit 12, the bias generator 13 and a bias selector 16. The Role detector 14 that is newly added to the CCPHY 10 of the first working example is achieved to share the comparators CMP1 and CMP2 with the Powered-C connection detector 113 of the Source circuit 11 and the electric-current supply ability detector 123 of the Sink circuit 12, respectively. Hereinafter, the former is referred to as a powered-C connection detector/Role detector sharing circuit 113A, and the latter is referred to as an electric-current supply ability detector/Role detector sharing circuit 123A.

The bias generator 13 outputs the reference voltages of four types (VREF1, VREF2, VREF3 and VREF4) having different voltage values to the Source and Sink detectors (112, 122, 113A and 123A) as similar to FIG. 4, and besides, outputs the reference voltages (VREF5 and VREF6) for the Role detection to the comparators CMP of the powered-C connection detector/Role detector sharing circuit 113A and the electric-current supply ability detector/Role detector sharing circuit 123A.

The bias selector 16 has a selector SEL that selects the reference voltages (VREF3 and VREF4) for the Powered-C detection and the electric-current supply ability detection or the reference voltages (VREF5 and VREF6) for the Role detection. The input terminal EN4 is used for selecting the reference voltages (VREF3/VREF4 or VREF5/VREF6), and the selected voltages (VREF7 and VREF8) are supplied to the powered-C connection detector/Role detector sharing circuit 113A and the electric-current supply ability detector/Role detector sharing circuit 123A. The bias selector 16 outputs the voltage values of the reference voltages (VREF3 and VREF4) as the reference voltages (VREF7 and VREF8) at the time of the normal operation, or outputs the voltage values of the reference voltages (VREF5 and VREF6) as the reference voltages (VREF7 and VREF8) at the time of the Role detection.

At the time of the Role detection, the comparator CMP of the powered-C connection detector/Role detector sharing circuit 113A outputs the determination result of the input voltage level of the CC1 terminal to the output terminal CC1OUT3, and outputs the determination result of the input voltage level of the CC2 terminal to the output terminal CC2OUT3. The comparator CMP of the electric-current supply ability detector/Role detector sharing circuit 123A outputs the determination result of the input voltage level of the CC1 terminal to the output terminal CC1OUT4, and outputs the determination result of the input voltage level of the CC2 terminal to the output terminal CC2OUT4.

Note that the configurations of the electric-current output circuit 111, the pulldown resistor 121, the Sink-connection detector 112 and the Source-connection detector 122 are the same as those of the CCPHY 10 of the first working example in the configuration, and therefore, the explanation for them will be omitted.

One configuration example of the second working example can be summarized as follows although not particularly limited.

The semiconductor device includes the type-C controller 30 (see FIG. 13) and the CCPHY 10a.

The CCPHY 10a is configured to include: the electric-current output circuit 111 including the first switch SW1 for use in disabling the electric-current output Ip; the Source circuit 11 including the Sink-connection detector circuit 112 having the comparator and the powered-C connection detector/Role detector sharing circuit 113A; the Sink circuit 12 including the pulldown resistor 121 including the second switch SW2 for use in disabling the pulldown resistance Rd, the Source-connection detector 122 having the comparator and the electric-current supply ability detector/Role detector sharing circuit 123A; the bias generator 13 supplying the reference voltages (VREF1 to VREF6) to each of the detectors/Role detector (112, 113A, 122 and 123A); and the bias selector 16 including the selector SEL and switching the reference voltages at the time of the normal operation and the Role detection to the powered-C connection detector/Role detector sharing circuit 113A and the electric-current supply ability detector/Role detector sharing circuit 123A.

The Type-C controller 30 simultaneously turns ON the first switch SW1 and the second switch SW2 in the DRP Timing period defined in the Type-C standards, and then, detects the role of the counterpart device 20 by using the powered-C connection detector/Role detector sharing circuit 113A and the electric-current supply ability detector/Role detector sharing circuit 123A to compare the reference voltages (VREF5 and VREF6) with the voltage levels (V1 to V4) of the CC terminal depending on the connection state of the counterpart device 20.

In addition to the first and second effects of the first working example, the CCPHY 10a of the second working example has a third effect capable of suppressing the increase of the circuit scale due to the addition of the function by making the comparator CMP for the Power-C connection detection and the electric-current supply ability detection and the comparators CMP1 and CMP2 for the Role detection to be shared.

In the foregoing, the invention made by the present inventors has been concretely described on the basis of the working examples. However, it is needless to say that the present invention is not limited to the foregoing embodiments and working examples, and various modifications can be made.

What is claimed is:

1. A connection detector comprising:
a power supply line for use in supply of a power supply potential;
a CC terminal;
a ground terminal;
an electric-current output circuit arranged between the power supply line and the CC terminal and including a first switch for use in disabling an electric-current output;
a pulldown resistor circuit arranged between the CC terminal and the ground terminal and including a second switch for use in disabling a pulldown resistance;
a bias circuit configured to generate a first reference potential and a second reference potential that is different from the first reference potential; and
a role detector including a first comparator configured to compare the first reference potential with a voltage of the CC terminal and a second comparator configured to compare the second reference potential with a voltage of the CC terminal,
wherein the first switch and the second switch are simultaneously turned ON in a Dual Role Power (DRP) period defined in the Universal Serial Bus (USB) Type-C standards, and then, a role of a counterpart device is detected by using the Role detector to compare the first and second reference potentials with the voltage level of the CC terminal depending on a connection state with the counterpart device.

2. The connection detector according to claim 1,
wherein the CC terminal includes a CC1 terminal and a CC2 terminal, and
each of the CC1 terminal and the CC2 terminal is provided with the electric-current output circuit, the pulldown resistor and the role detector.

3. The connection detector according to claim 1 further comprising:
a source circuit including a sink-connection detector and a powered-cable detector; and
a sink circuit including a source-connection detector and an electric-current supply ability detector.

4. The connection detector according to claim 3,
wherein each of the sink-connection detector, the powered-cable detector, the source-connection detector and the electric-current supply ability detector includes a comparator configured to compare a corresponding reference potential with a voltage of the CC terminal, and
the bias circuit is configured to generate the corresponding reference potential.

5. The connection detector according to claim 4,
wherein the CC terminal includes a CC1 terminal and a CC2 terminal, and
each of the CC1 terminal and the CC2 terminal is provided with the electric-current output circuit, the pulldown resistor, the role detector, the sink-connection detector, the powered-cable detector, the source-connection detector and the electric-current supply ability detector.

6. A semiconductor device comprising:
a Type-C controller;
a connection detector;
a power supply line for use in supply of a power supply potential;
a CC terminal; and
a ground terminal,
wherein the connection detector includes:
an electric-current output circuit arranged between the power supply line and the CC terminal and including a first switch for use in disabling an electric-current output;
a pulldown resistor circuit arranged between the CC terminal and the ground terminal and including a second switch for use in disabling a pulldown resistance;
a bias circuit configured to generate a first reference potential and a second reference potential that is different from the first reference potential; and
a role detector including a first comparator configured to compare the first reference potential with a voltage of the CC terminal and a second comparator configured to compare the second reference potential with a voltage of the CC terminal, and
the Type-C controller simultaneously turns ON the first switch and the second switch in a Dual Role Power (DRP) period defined in the Universal Serial Bus (USB) Type-C standards, and then, detects a role of a counterpart device by using the role detector to compare the first and second reference potentials with the voltage level of the CC terminal depending on a connection state with the counterpart device.

7. The semiconductor device according to claim 6,
wherein the CC terminal includes a CC1 terminal and a CC2 terminal, and
each of the CC1 terminal and the CC2 terminal is provided with the electric-current output circuit, the pulldown resistor and the role detector.

8. The semiconductor device according to claim 6 further comprising:
a source circuit including a sink-connection detector and a powered-cable detector; and
a sink circuit including a source-connection detector and an electric-current supply ability detector.

9. The semiconductor device according to claim 8,
wherein each of the sink-connection detector, the powered-cable detector, the source-connection detector and the electric-current supply ability detector includes a comparator configured to compare a corresponding reference potential with a voltage of the CC terminal, and
the bias circuit is configured to generate the corresponding reference potential.

10. The semiconductor device according to claim 9,
wherein the CC terminal includes a CC1 terminal and a CC2 terminal, and
each of the CC1 terminal and the CC2 terminal is provided with the electric-current output circuit, the pulldown resistor, the role detector, the sink-connection detector, the powered-cable detector, the source-connection detector and the electric-current supply ability detector.

11. A connection detector comprising:
a power supply line for use in supply of a power supply potential;
a CC terminal;
a ground terminal;
an electric-current output circuit arranged between the power supply line and the CC terminal and including a first switch for use in disabling an electric-current output;
a source circuit including a sink-connection detector having a comparator and a powered-cable connection detector/role detector sharing circuit;
a sink circuit including a pulldown resistor including a second switch for use in disabling a pulldown resistance, a source-connection detector having a comparator and an electric-current supply ability detector/role detector sharing circuit;
a bias generator configured to supply a corresponding reference voltage to each corresponding comparator of the sink-connection detector, the powered-cable connection detector/role detector sharing circuit, the source-connection detector and the electric-current supply ability detector/role detector sharing circuit; and
a bias selector including a selector and configured to switch the reference voltages at the time of normal operation and role detection, the voltages being supplied to the powered-cable connection detector/role detector sharing circuit and the electric-current supply ability detector/role detector sharing circuit,
wherein the first switch and the second switch are simultaneously turned ON in a Dual Role Power (DRP) period defined in the Universal Serial Bus (USB) Type-C standards, and then, a role of a counterpart device is detected by using each comparator of the powered-cable connection detector/role detector sharing circuit and the electric-current supply ability detector/role detector sharing circuit to compare the corresponding reference potential with the voltage level of the CC terminal depending on a connection state with the counterpart device.
